(19) United States
(12) Patent Application Publication
(10) Pub. No.: US 2020/0226519 A1
(43) Pub. Date: Jul. 16, 2020

(54) SYSTEM AND METHOD FOR MANAGING RESOURCES IN A WORKSITE

(71) Applicant: ARTH DESIGNBUILD INDIA PVT. LTD., Jubilee Hills, Hyderabad (IN)

(72) Inventors: Thumu Karthik, Hyderabad, Telangana (IN); Kailash Chandola, Hyderabad, Telangana (IN); Swapnil Sahu, Hyderabad, Telangana (IN); Anshul Gargya, Hyderabad, Telangana (IN); Kevin Jasti, Hyderabad, Telangana (IN)

(21) Appl. No.: 16/632,426

(22) PCT Filed: May 16, 2018
(86) PCT No.: PCT/IN2018/050311

§ 371 Date: Jan. 20, 2020

(30) Foreign Application Priority Data
Jul. 25, 2017 (IN) 201741026310

(51) Int. Cl. G06Q 10/06; G06Q 10/04; G06Q 50/08; G06Q 10/08; G06F 30/13; G06N 5/04

(52) U.S. Cl. CPC G06Q 10/06315; G06Q 10/04; G06Q 50/08; G06Q 10/0875; G06N 5/04; G06Q 10/06395; G06Q 10/067; G06F 30/13; G06Q 10/06393

(57) ABSTRACT

A system and a method for managing resources, using prediction models for estimating required resources for a selected activity in the worksite, is disclosed. This involves capturing object data related to actual resources utilized for the selected activity; and further accessing, from the BIM files, historic data about consumed resources for one or more other activities similar to the selected activity. A preliminary prediction model is used to estimate required resources for the selected activity by extrapolating the historic data related to consumed resources associated with the one or more other activities. Further, a variance between the estimated required resources and actual resources utilized is calculated for the selected activity, and the obtained information is utilized to refine the said preliminary prediction model so that it may provide better prediction for subsequent request for queries related to estimation of resources for any activity in the worksite.

### FIELD OF THE PRESENT DISCLOSURE

The present disclosure generally relates to resource management in a worksite, and more particularly to a system and a method for managing resources in a worksite by adopting machine learning techniques.

### BACKGROUND

Construction is a complex process and involves an array of collaboration, management planning and execution. The process of construction can vary significantly depending on the scope of the project and the particulars of the structure. Any construction project involves a large number of resources including labour, material and monetary resources. This demands their management in association with their connection to activities, such as procurement of construction material, hiring of labour, defining time schedule specifying the start and end dates of tasks, effective organization of tasks and resources to maximize efficiency. Successful execution of construction project is dependent upon the proper pre-planning, procurement, execution and resource management, for example proper resources being available at the right time for any given construction activity. Some estimates suggest that up to 35% of costs in any construction project can possibly go into material waste and remedial work if the resources in the worksite are not properly managed.

In construction process, a lot of data is generated from the worksite which needs to be updated to heads of various departments in real time which would help them to take timely decisions to make sure of maximum utilization of resources leading to better project management. Traditional analysis of datasets collected from the worksite is achieved through lot of paperwork which, although, could help increase productivity of a given construction process, but is generally tedious and expensive. Modern techniques for analysis include using digital methods, such as Building Information Modelling (BIM) which could help the user to understand the entire lifecycle of construction process at any stage, and further make effective and correct decisions about managing the project based on accurate and complete data. BIM models include information about the different resources; however, such information may not always be sufficient to take decisions for the project management.

U.S. Pat. No. 8,626,698 relates to a method and system for determining probability of project success. The document provides a computer-implemented method for developing a model to estimate a probability of project success using historical data and predictive modelling. Although the document determines the project success rate based on historical data, the document fails to consider current material rate, quality variances, time required in transportation of materials, etc., and thus could not satisfactorily factor in the uncertainty due to these aspects.

Chinese Patent Application No. 105,023,201 relates to a method of assembling a large building using BIM-based data in order to improve the assembly of building design and the entire process control. The document provides the use of BIM and big data for construction and project cost analysis. The document particularly provides the techniques for cost analysis and inventory management using big data. However, the document does not provide any means for resource management using big data, for example, for project managers to get information about required resources in real time, time and costs associated with any given task, or quality against a given task.

U.S. Publication No. 20170109422 relates to system and method for generating actionable intelligence and information by utilizing big data. The document proposes to use multiple high-end technologies like Augmented Reality (AR), Virtual Reality (VR), motion tracking and the like, for such purpose. The use of such technologies incurs lot of up-front cost and thus hard to implement in all kinds of projects. Furthermore, the document does not particularly provide any information about resource management which could help make decisions for procurement of required resources for a particular activity in the worksite.

Accordingly, there is a need of systems and methods which could perform predictive analysis using metrics and algorithms to provide mapping of historical and real-time data in order to determine required resources, minimum time of completion, maximum efficiency and minimum deviation from the plan for any given activity in a worksite, and further aid in decision making for procurement of resources for the said activity and tracking of said activity in a project.

### SUMMARY

In one aspect, a method for managing resources in a worksite is provided. The method comprises capturing object data related to actual resources utilized for a selected activity in the worksite. The method also comprises accessing, over a computer network, a database comprising Building Information Modelling (BIM) files for the worksite. The BIM files comprises historic data about consumed resources for multiple activities in the worksite. The method further comprises identifying, from the BIM files, one or more other activities similar to the selected activity. The method further comprises estimating, using a prediction model, required resources for the selected activity by extrapolating the historic data related to consumed resources associated with the one or more other activities. The method also comprises calculating a variance between the estimated required resources and actual resources utilized for the selected activity. The method further comprises providing an output based on the calculated variance.

In another aspect, a system for managing resources in a worksite is provided. The system comprises a data collection unit connected to a computer network and configured to capture object data related to actual resources utilized for a selected activity in the worksite in the worksite. The system also comprises a central server. The central server comprises a database accessible over the computer network and comprising Building Information Modelling (BIM) files for the worksite. The BIM files comprising historic data about consumed resources for multiple activities. The central also server comprises a processing module configured to: identify, from the BIM files, one or more other activities similar to the selected activity; estimate, using a prediction model, required resources for the selected activity by extrapolating the historic data related to consumed resources associated with the one or more other activities; calculate a variance between the estimated required resources and actual resources utilized for the selected activity; and provide an output based on the calculated variance.

In yet another aspect, a computer-implemented method for managing resources in a worksite is provided. The computer-implemented method is performed by one or more processors configured by executing a code that cause the one or more processors to: capture object data related to actual resources utilized for a selected activity in the worksite; access, over a computer network, a database comprising Building Information Modelling (BIM) files for the worksite, wherein the BIM files comprising historic data about consumed resources for multiple activities in the worksite; identify, from the BIM files, one or more other activities similar to the selected activity; estimate, using a prediction model, required resources for the selected activity by extrapolating the historic data related to consumed resources associated with the one or more other activities; calculate a variance between the estimated required resources and actual resources utilized for the selected activity; and provide an output based on the calculated variance.

### BRIEF DESCRIPTION OF THE FIGURES

For a more complete understanding of example embodiments of the present disclosure, reference is now made to the following descriptions taken in connection with the accompanying drawings in which:

FIG. 1 illustrates a schematic representation of a system for managing resources in a worksite, in accordance with an example embodiment of the present disclosure;

FIG. 2 illustrates a flowchart representing a method for managing resources in the worksite, in accordance with an example embodiment of the present disclosure; and

FIG. 3 illustrates a schematic diagram of a procurement application, in accordance with an example embodiment of the present disclosure.

### DETAILED DESCRIPTION

In the following description, for purposes of explanation, numerous specific details are set forth in order to provide a thorough understanding of the present disclosure. It will be apparent, however, to one skilled in the art that the present disclosure can be practiced without these specific details. In other instances, apparatuses and methods are shown in block diagram form only in order to avoid obscuring the present disclosure.

Reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification are not necessarily all referring to the same embodiment, nor are separate or alternative embodiments mutually exclusive of other embodiments. Further, the terms “a” and “an” herein do not denote a limitation of quantity, but rather denote the presence of at least one of the referenced item. Moreover, various features are described which may be exhibited by some embodiments and not by others. Similarly, various requirements are described which may be requirements for some embodiments but not for other embodiments.

The present disclosure implements a computer program which embodies the functions described herein and illustrated in the appended flow charts. The processes and operations performed by the computer include the manipulation of signals by a processing unit or remote server and the maintenance of these signals within data structures resident in one or more of the local or remote memory storage devices. Such data structures impose a physical organization upon the collection of data stored within a memory storage device and represent specific electrical or magnetic elements. These symbolic representations are the means used by those skilled in the art of computer programming and computer construction to most effectively convey teachings and discoveries to others skilled in the art.

Embodiments of the present disclosure relates to a computer code stored on a media for performing various computer-implemented operations. The media and computer code may be those specially designed and constructed for the purposes of the present disclosure, or they may be of the kind well known and available to those having skill in the computer software arts. Examples of computer-readable media include, but are not limited to: magnetic media such as hard disks, floppy disks, and magnetic tape; optical media such as CD-ROMs, DVDs and holographic devices; magneto-optical media; and hardware devices that are specially configured to store and execute program code, such as application-specific integrated circuits (“ASICs”), programmable logic devices (“PLDs”) and ROM and RANI devices. Examples of computer code include machine code, such as produced by a compiler, and files containing higher-level code that are executed by a computer using an interpreter. For example, an embodiment of the invention may be implemented using a general programming language, JAVA®, C++, or another object-oriented or non-object-oriented programming language and development tools. Another embodiment of the invention may be implemented in hardwired circuitry in place of, or in combination with, machine-executable software instructions.

It should be apparent that there could be many different ways of implementing the disclosure in computer programming, and the disclosure should not be construed as limited to any one set of computer program instructions. Further, a skilled programmer would be able to write such a computer program to implement the disclosed invention without difficulty based on the flow charts and associated description in the application text. Therefore, disclosure of a particular set of program code instructions is not considered necessary for an adequate understanding of how to make and use the present disclosure. The inventive functionality will be explained in more detail in consideration of the following description read in conjunction with the appended figures.

The embodiments are described herein for illustrative purposes and are subject to many variations. It is understood that various omissions and substitutions of equivalents are contemplated as circumstances may suggest or render expedient, but are intended to cover the application or implementation without departing from the spirit or the scope of the present disclosure. Further, it is to be understood that the phraseology and terminology employed herein are for the purpose of the description and should not be regarded as limiting. Any heading utilized within this description is for convenience only and has no legal or limiting effect.

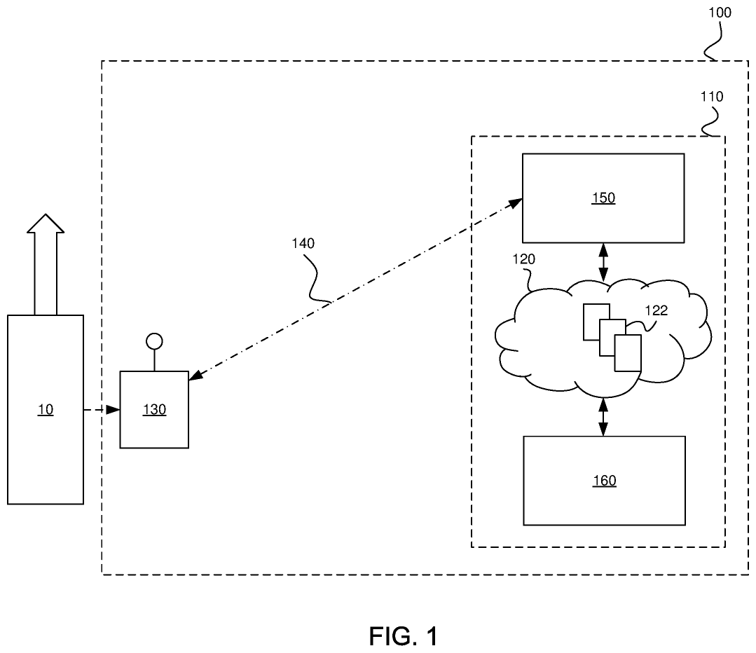

Various embodiments of the present disclosure are related to systems and methods for managing resources. FIG. 1 schematically illustrates a system 100 for managing resources in a worksite 10. The “worksite” as referred herein may include, but not limited to, a “construction site;” and hereinafter the two terms have been interchangeably used. The worksite 10 generally involves large number of labour resources and material resources which needs to be managed as per a predefined plan. The construction activities are dependent upon the proper resources being available at the right time for completing the construction process within the defined timelines. Conditions within the construction site can vary wildly from location-to-location and across time, and therefore suitable computation systems may be needed which could monitor and manage resources for efficient execution of work, while being mobile, robust, customizable and easy to use. The system 100 of the present disclosure provides predictive analysis of labour and material resources, including time and money required for a selected activity in the worksite 10. An “activity” as referred herein may correspond to any particular construction operation in the worksite 10, e.g., laying of foundation at location A. The predictive analysis could help in performance evaluation of subcontractors, asset management, predictive maintenance, predictive schedule analysis, improving safety of the construction work, preventive maintenance and the like. The present system 100 further provides suggestions for procurement based on historical data of seasonal variation of cost, quality and availability the resources, such as building construction material.

In accordance with an embodiment, the system 100 is based on Building Information Modelling (BIM), which is also sometimes referred to as “building information model.” BIM is generally used in large construction projects and generally provides a three-dimensional (3D) design of the structures at the worksite 10. The said design for the worksite 10 may include any relevant data, drawings, properties, information, images, model(s), etc. stored in any suitable non-transitory computer-readable medium. In any instances herein in which the term “BIM” is used, it is meant to refer to any suitable design or related data known in the art. In the present example, BIM further extends beyond 3D, augmenting the three primary spatial dimensions (width, height and depth) with time as the fourth dimension (4D) and cost as the fifth dimension (5D). Therefore, BIM is not limited to the planning and design phase of the project, and extends throughout the life cycle of the project, e.g., for supporting processes including cost management, construction process tracking and management, project management and facility operation.

As schematically illustrated in FIG. 1, the system 100 comprises a central server 110 which process the information received from various sources to provide plans for monitoring and management of resources in the worksite 10. In accordance with some examples, the central server 110 may be located on-site, i.e. in the worksite 10 itself. In some other examples, the central server 110 may be located remotely to the worksite 10. In still other examples, the central server 110 may have some of its components located at the worksite 10 and other components located remotely to the worksite 10, without any limitations. It shall be understood that the central server 110 acts as a data and processing repository, in which multiple units executes a coordinated computer code to analyse the data associated with the selected activities in the worksite 10 to come up with better prediction models for more accurate estimate of required resources for any given activity in the worksite 10 by using certain metrics, and thereby improves management of resources therein.

For this purpose, the central server 110 comprises a database 120. The database 120 may be configured to handle data management, including historical data and statistics, user accounts, among other data related to the activities in the worksite 10. In one example, the database 120 may have the capability to handle large amounts of data spread across many unit servers to provide a reliable service with no single point of failure. In one or more embodiments of the present disclosure, the database 120 may be configured to store building information models, i.e. BIM files 122 for the worksite 10. It may be contemplated that the database 120 may include one or more storage mediums, such as, but not limited to, hard drives, solid state drives, magnetic tapes, etc. for storage of the BIM files 122 therein. In some examples, the database 120 may be a cloud-based database which allows for the BIM files 122 to be stored in a single, central location where it can be catalogued, sorted, compared, linked and updated. The BIM files 122 may include information about construction schedule, costs, materials specifications, etc., in addition to the design of buildings for the worksite 10. In one example, the BIM files 122 may also include information about historic data about consumed resources for multiple activities in the worksite 10, and possibly other worksites. BIM files 122 are often, but not always, in proprietary formats and contains proprietary data which can be extracted, exchanged or networked to support decision-making regarding a structure or other assets in the worksite 10.

As discussed, the system 100 provides predictive analysis of labour and material resources required for a selected activity in the worksite 10. According to an embodiment, the system 100 of the present disclosure include means to capture object data related to actual resources being utilized for completion of the selected activity in the worksite 10. Such data about the actual resources is utilized for comparison with the results of the predictive analysis and/or the available information from the BIM files 122 in order to understand the effectiveness of the prediction model. In some examples, the results of the comparison are fed back into the prediction model, and as more and more such results are fed, accuracy of the prediction model improves. It may be contemplated by a person skilled in the art that the techniques described above are based on machine learning and artificial intelligence techniques which are well known in the art; and thus the details have not been not included herein for the brevity of the present disclosure.

Referring to FIG. 1, the system 100 comprises a data collection unit 130 in accordance with an embodiment of the present disclosure. The data collection unit 130 is configured to capture object data related to actual resources utilized for the selected activity in the worksite 10. In one example, the data collection unit 130 achieves this by allowing a user at the worksite 10 to manually enter one or more parameters about the selected activity. Typical worksite, such as the worksite 10 has various personnel that are assigned tasks and scheduled to work at specific construction location at specific times during the construction process. To capture the object-oriented data, one of the users is assigned a construction location associated with the selected activity, and the assigned user may employ the data collection unit 130 to capture the object data including one or more predefined parameters for the selected activity.

For this purpose, the data collection unit 130 may include a portable computing device, such as, but not limited to, a smartphone (e.g., Android or iOS based), a tablet (e.g., an iPad), a PDA, laptop, or any other handheld device. In at least one example, the data collection unit 130 may provide a software application which may be downloaded from a remote application store or a remote server onto the data collection unit 130 over a communication network. In other examples, the application may be pre-installed in the data collection unit 130 and may not require the user to download the application therein. The application provides the user with an interface to enter the said one or more parameters as described above. In other examples, the data collection unit 130 may provide the user with an access to a website or a web application. In such scenario, the user may utilize a web browser application on the data collection unit 130 to access a web server storing one or more web pages and UIs to enable the user to enter the one or more parameters. Alternatively, the data collection unit 130 may include one or more sensors which may automatically capture object data for the selected activity. For example, the data collection unit 130 may include Internet Protocol (IP) based cameras commonly employed for surveillance that can send and receive data via a computer network and the Internet. It may be understood that such IP cameras may implement computer vision, artificial intelligence and similar techniques to determine one or more parameters of the selected activity, as discussed above.

In one implementation, the data collection unit 130 provides an interface with a login page and a landing page, such that the login page asks for valid credentials to authenticate the user. For this purpose, the central server 110 may include any applicable web server, for example, Apache™, Node.js, etc., that supports a web application framework. The web based platform provides services such as, for example, authentication, dynamic web page generation and an interface front end, among others. Upon validation, the landing page displays variable functionalities depending on the received credential data, and such functionalities may be categorized, in one example, into various tabs labelled “Projects”, “Checklist”, “Notifications” and “Setting.” The “Projects” tab shows list of all ongoing activities in the worksite 10, including the selected activity. The “Checklist” tab shows list of activities assigned to the user, and further allows the user to select one of the activity. The “Notifications” tab may allow the user to receive updates from the central server 110, e.g. instructions to check a particular activity. The “Setting” tab may allow the user to change the behaviour of the software application. It may be contemplated that the described interface for the software application is exemplary only and may vary based on the project requirement.

Further, in an embodiment, the data collection unit 130 is connected to a computer network 140, such as a local area network (LAN) or the Internet via Wi-Fi or some other means. The data collection unit 130 may upload the captured object data for the selected activity to the database 120 which is also connected to the same computer network 140. In the database 120, the captured object data is aggregated into the BIM files 122 stored therein. In some examples, the data collection unit 130 may further include its location information in the captured data, so that it could be confirmed that the tagged object data is associated with the selected activity in the worksite 10. In one example, the data collection unit 130 may use one or a combination of Global Positioning System (GPS), Global Navigation Satellite System (GLONASS), Galileo system, Indian Regional Navigation Satellite System (IRNSS), Beidou system, triangulation or trilateration of cellular or Wi-Fi networks, and other similar methods for determining location information. In some examples, the central server 110 may include a signal receiving module 150 to facilitate connection with the computer network 140 and configured to receive the captured object data by the data collection unit 130. Communication in and among computers, I/O devices and network devices may be accomplished using a variety of protocols. Protocols may include, for example, signalling, error detection and correction, data formatting and address mapping. For example, protocols may be provided according to the seven-layer Open Systems Interconnection model (OSI model), the TCP/IP model, or any other suitable model.

According to an embodiment, the central server 110 further comprises a processing module 160 which is configured to execute the prediction model. The processing module 160 may include a processor and a memory operatively coupled with each other. The memory may be capable of storing machine executable instructions, and the processor may be capable of executing the stored machine executable instructions for performing tasks such as parsing data from the database 120, execution of the prediction model, etc. Examples of the memory include, but are not limited to, volatile and/or non-volatile memories. For instance, the memory may be volatile memory (e.g., registers, cache, RAM), non-volatile memory (e.g., ROM, EEPROM, flash memory, etc.), or some combination of the two. The memory stores software, for example, set of instructions that can, for example, implement the technologies described herein, upon execution. For example, the memory may be configured to store information, data, applications, instructions for enabling the processing module 160 to carry out various functions. The processor may be embodied as a multi-core processor, a single core processor, or a combination of one or more multi-core processors and one or more single core processors. For example, the one or more processors may be embodied as one or more of various processing devices, such as a coprocessor, a microprocessor, a controller, a digital signal processor (DSP), a processing circuitry with or without an accompanying DSP, or various other processing devices including integrated circuits such as, for example, an application specific integrated circuit (ASIC), a field programmable gate array (FPGA), a microcontroller unit (MCU), a hardware accelerator, a special-purpose computer chip, or the like. It may be understood that the processing module 160 may be a distributed or a unified system, without any limitations.

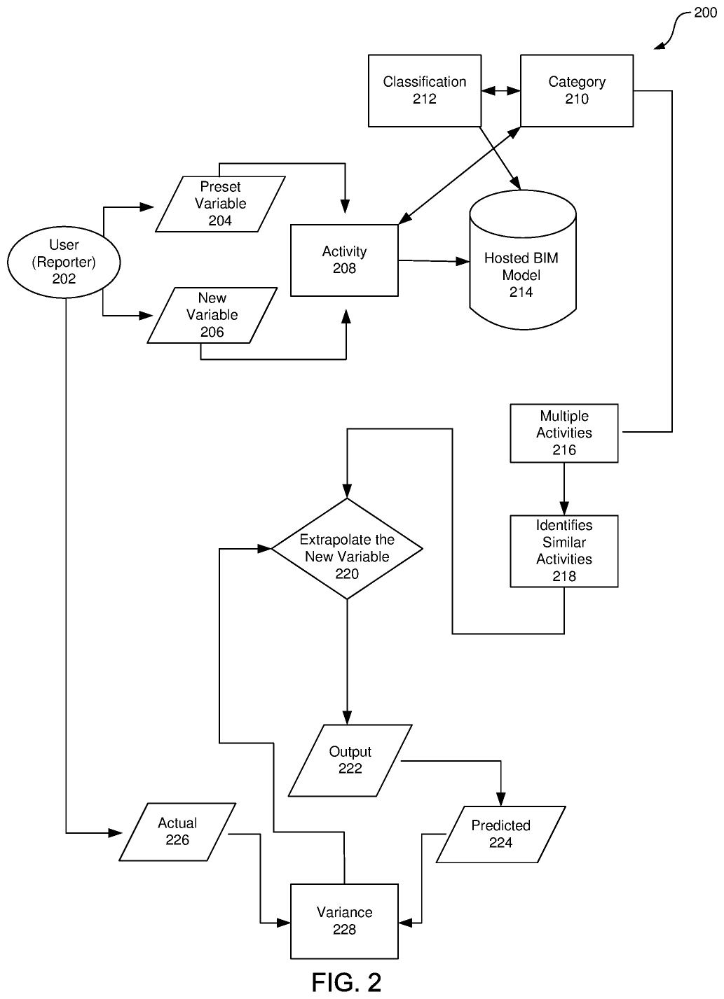

FIG. 2 illustrates a flowchart 200 representing a method for managing resources in a construction site, such as the worksite 10. In particular, the flowchart 200 depicts a sequence of events for refining the predictive model for obtaining more accurate information about required resources for any selected activity in the worksite 10. In block 202, the user reports and captures the object data directly from the selected activity in the worksite 10, via the data collection unit 130. The data collection unit 130 allows the user to update the BIM files 122 utilizing the captured data. For example, the data collection unit 130 may provide the user with option to either edit a “pre-set variable” as in block 204, or define a “new variable” as in block 206. In block 208, the captured data is aggregated into the BIM files 122 associated with the selected activity. For such purpose, as shown in block 210 and block 212, the captured data may be classified for organization of BIM content and categorized for grouping with BIM content, respectively, and for further updating the BIM files 122 in the database 120, as in block 214. The classification and categorization of the data may be implemented based on one of the two known popular standards; MasterFormat and UniFormat. MasterFormat is used to capture information on detailed construction documents, such as construction plans and product specifications; whereas, UniFormat is used to capture an expanded set of important project-related documents. Each system classified information in a different way; e.g., MasterFormat by work results and UniFormat by functional elements. The two systems work in a complementary fashion to facilitate effective documentation management. It may be understood that all the activities in the BIM files 122 are classified and categorized using the chosen standard for data compatibility purposes.

In block 216, the processing module 160 may access the database 120 to parse through the multiple activities as defined in the BIM files 122 for the worksite 10. Next, in block 218, the processing module 160 may identify, from the BIM files 122, one or more other activities similar to the selected activity. It may be understood that any suitable searching algorithm(s) may be employed for such identification purposes. The processing module 160 may further extract the information about the consumed resources associated with the identified one or more other activities. In block 220, the processing module 160 extrapolates the historic data related to consumed resources associated with the one or more other activities to estimate required resources for the selected activity. It may be contemplated by a person skilled in the art that the processing module 160 implements this using a prediction model. In block 222, the processing module 160 provides an output indicative of the required resources estimated for the selected activity, and display such information for perusal of a user, e.g. the project manager for the worksite. It may be understood that the above steps may be implemented to estimate required resources for any activity in the worksite 10 when no initial information is available, and such estimate may be used for managing resources in the worksite 10 as will be discussed later in more detail.

Moving on, the next steps provide for refining of the prediction model so as to obtain more accurate information about required resources for any selected activity in the worksite 10. As shown, in block 224, the information about actual resources utilized for the selected activity is extracted from the captured object data obtained from the block 202. Further, in block 226, the information about predicted resources for the selected activity is extracted from the estimate obtained from the block 222. In block 228, a variance is determined between the data for predicted resources and actual resources associated with the selected activity. It may be understood that the variance is calculated as the result of difference between the values of the predicted resources and the actual resources. As depicted in the flowchart 200, this variance information is fed back to the block 220 for refining the prediction model used therein. These refined prediction model may be updated in the BIM files stored in the database 120. Since the present software is web based and the corresponding BIM files are stored in the cloud; once the obtained refined models will be synced to the cloud, the updated prediction models are almost instantly available to be employed by users of the present software for any construction site across the globe to be able to better estimate the resources required for any applicable activity which is similar to the selected activity herein.

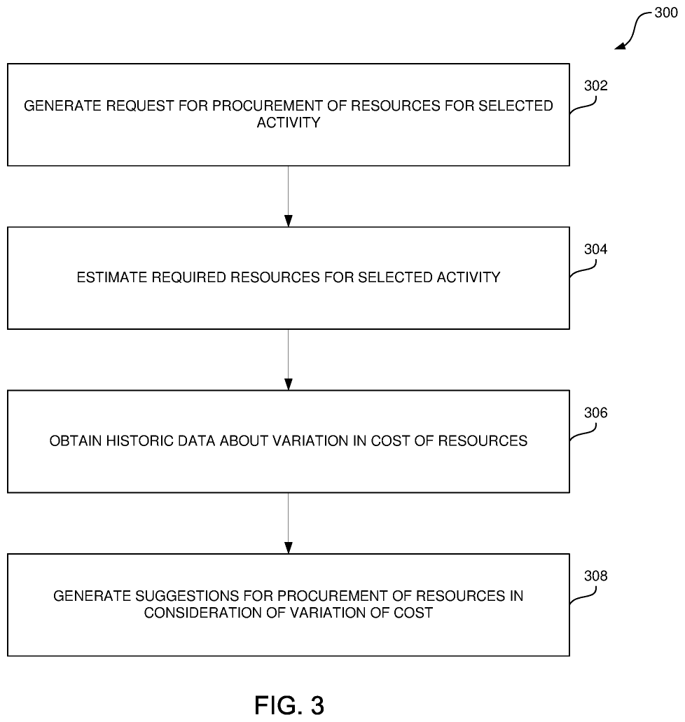

According to an embodiment, the refined prediction models obtained by implanting the above steps are utilized to generate suggestions for procurement of resources for the various activities in the worksite 10. FIG. 3 illustrates a schematic diagram 300 of a procurement application, to depict the steps involved in the procurement of resources using the said application. In one implementation, as in block 302, the user may generate a request for procurement of resources for a selected activity using, e.g., a web application or a dedicated mobile application. In block 304, the procurement application, using the refined prediction models of the present disclosure, may estimate the required resources for the selected activity. In block 306, the procurement application accesses the BIM files which include historic data about time or seasonal variation of cost of resources, quality of resources, and availability of resources. In block 306, the procurement application generates suggestions for procurement of resources in consideration of the said time or seasonal variation of: cost of resources, quality of resources, and/or availability of resources. That is, the procurement application may choose to place an order with a vendor for the estimated number of resources when it is predicted that the overall cost to obtain the resources is minimal and/or the quality of the obtained resources is best possible, within the constraints of the timelines for completion of the construction process. In some examples, the procurement application may further factor in conditions like financial budgeting and credit time required. In one implementation, the procurement application further utilizes machine learning and similar techniques to generate better models for making improved suggestions for procurement of resources.

In one implementation, the one or more parameters comprises information indicative of quality of resources utilized for the selected activity. In such case, the object-oriented data is analysed to benchmark multiple vendors associated with the selected activity based on the quality of resources utilized for the selected activity. Further, in some examples, the updated BIM files may be utilized to manage schedule for delivery of resources for the multiple activities in the worksite 10, such as to obtain the resources when the cost is minimal and/or the quality of the obtained resources is best possible. In some examples, the provided output based on the calculated variance between predicted resources and actual resources is also utilized to benchmark different cost and/or quantities of resources available for the worksite. That is, less the variance better the prediction model and vice-versa. Such information can be employed to select which benchmark to be used for managing resources in a worksite.

It may be contemplated that in a construction process, the timing of the delivery of materials can be critical. The construction activities are dependent upon the proper materials being available for construction. It is expensive and wasteful for a construction crew to be at a job location, but have insufficient inventory of building materials to begin or complete the construction task. This situation results in lost time and money and can even result in penalties to the construction company for missing construction deadlines. Therefore, it is advantageous to schedule delivery of materials to the construction location in relation to the progress of the project so that materials are delivered to the construction location when needed. It is not advantageous to purchase the complete list of materials for a specific construction site as this can result in an unnecessary outward cash flow, inventory storage problems and inventory shrinkage problems due to theft or spoilage due to materials being exposed to the elements for too long.

The proposed system and method of the present disclosure provide advance prediction models which are able to predict with sufficient accuracy about the resources required for any given activity, as well as the time when such resources may be needed. With this information, the user, e.g., the project manager can better manage the resources in the worksite 10. The present disclosure can further be used for performance evaluation of subcontractors, asset management, predictive maintenance, predictive schedule analysis, improving safety of the construction work etc. The present system makes it easier for management and planning team to make data-driven decisions. This will result in faster delivery of a project, reduction in wastage of material at the worksite and better return on investment (ROI). Further, the present disclosure provides vendor benchmarking which may also help with selection of best pricing of quality material from various vendors. The present disclosure also provides a benefit in that it can be used to track materials at a construction location.

The foregoing descriptions of specific embodiments of the present disclosure have been presented for purposes of illustration and description. They are not intended to be exhaustive or to limit the present disclosure to the precise forms disclosed, and obviously many modifications and variations are possible in light of the above teaching. The exemplary embodiment was chosen and described in order to best explain the principles of the present disclosure and its practical application, to thereby enable others skilled in the art to best utilize the present disclosure and various embodiments with various modifications as are suited to the particular use contemplated.

I/We claim:

1. A method for managing resources in a worksite, comprising:
capturing object data related to actual resources utilized for a selected activity in the worksite;
accessing, over a computer network, a database comprising Building Information Modelling (BIM) files for the worksite, the BIM files comprising historic data about consumed resources for multiple activities in the worksite;
identifying, from the BIM files, one or more other activities similar to the selected activity;
estimating, using a prediction model, required resources for the selected activity by extrapolating the historic data related to consumed resources associated with the one or more other activities;
calculating a variance between the estimated required resources and actual resources utilized for the selected activity; and
providing an output based on the calculated variance.

2. The method of claim 1, wherein providing the output comprises refining the prediction model based on the calculated variance.

3. The method of claim 1, wherein the object data is captured by feeding, using a data collection unit connected to the computer network, one or more parameters about the selected activity.

4. The method of claim 1, further comprising updating the BIM files by aggregating the captured object data related to actual resources utilized for the selected activity into the BIM files.

5. The method of claim 2, wherein the refined prediction model is utilized to generate suggestions for procurement of resources for the activities in the worksite.

6. The method of claim 5, wherein the BIM files comprises historic data about time variation of: cost of resources, quality of resources, and availability of resources, and wherein the refined prediction model is utilized to generate suggestions for procurement of resources in consideration of one or more of the time variation of: cost of resources, quality of resources, and availability of resources.

7. The method of claim 1, wherein the updated BIM files are utilized to manage schedule for delivery of resources for the multiple activities in the worksite.

8. The method of claim 1, wherein the provided output is utilized to benchmark different BIM models available for the worksite.

9. The method of claim 3, wherein the one or more parameters comprises information about quality of resources utilized for the selected activity, and wherein the captured object data is utilized to benchmark vendors associated with the selected activity based on the available information about the quality of resources utilized.

10. A system for managing resources in a worksite, comprising:
a data collection unit connected to a computer network and configured to capture object data related to actual resources utilized for a selected activity in the worksite; and
a central server comprising:
a database accessible over the computer network and comprising Building Information Modelling (BIM) files for the worksite, the BIM files comprising historic data about consumed resources for multiple activities in the worksite; and
a processing module configured to:
identify, from the BIM files, one or more other activities similar to the selected activity;
estimate, using a prediction model, required resources for the selected activity by extrapolating the historic data related to consumed resources associated with the one or more other activities;
calculate a variance between the estimated required resources and actual resources utilized for the selected activity; and
provide an output based on the calculated variance.

11. The system of claim 10, wherein the processing module is configured to refining the prediction model based on the calculated variance.

12. The system of claim 10, wherein the data collection unit provides an interface to allow a user at the worksite to feed one or more parameters about the selected activity.

13. The system of claim 10, wherein the processing module is further configured to update the BIM files by aggregating the captured object data related to actual resources utilized for the selected activity into the BIM files.

14. The system of claim 11, wherein the processing module is further configured to utilize the refined prediction model to generate suggestions for procurement of resources for the activities in the worksite.

15. A computer-implemented method for managing resources in a worksite, the computer-implemented method performed by one or more processors configured by executing a code that cause the one or more processors to:
capture object data related to actual resources utilized for a selected activity in the worksite;
access, over a computer network, a database comprising Building Information Modelling (BIM) files for the worksite, the BIM files comprising historic data about consumed resources for multiple activities in the worksite;
identify, from the BIM files, one or more other activities similar to the selected activity;
estimate, using a prediction model, required resources for the selected activity by extrapolating the historic data related to consumed resources associated with the one or more other activities;
calculate a variance between the estimated required resources and actual resources utilized for the selected activity; and
provide an output based on the calculated variance.
